(19) United States
(12) Patent Application Publication
(10) Pub. No.: US 2025/0221147 A1
(43) Pub. Date: Jul. 3, 2025

(54) LIGHT-EMITTING DEVICE AND PREPARATION METHOD THEREFOR

(71) Applicant: TCL TECHNOLOGY GROUP CORPORATION, Huizhou, Guangdong (CN)

(72) Inventor: Kaimin CHEN, Huizhou, Guangdong (CN)

(73) Assignee: TCL TECHNOLOGY GROUP CORPORATION, Huizhou, Guangdong (CN)

(21) Appl. No.: 18/852,436

(22) PCT Filed: Nov. 2, 2022
(86) PCT No.: PCT/CN2022/129132

§ 371 Date: Sep. 27, 2024

(30) Foreign Application Priority Data
Apr. 7, 2022 (CN) 202210365346.6

(51) Int. Cl. H10K 50/115; H10K 50/15; H10K 71/12; H10K 102/00

(52) U.S. Cl. CPC H10K 50/115; H10K 50/15; H10K 71/12; H10K 2102/351

(57) ABSTRACT

Disclosed in the disclosure are a light-emitting device and a preparation method therefor. The light-emitting device includes a positive electrode, a hole transport layer, a light-emitting layer, and a negative electrode, which are arranged in a stacked manner.

The present disclosure claims priority to Chinese Patent Application No. 202210365346.6, filed in the China National Intellectual Property Administration on Apr. 7, 2022, and entitled “LIGHT-EMITTING DEVICE AND PREPARATION METHOD THEREFOR, AND DISPLAY APPARATUS”, which is incorporated herein by reference in its entirety.

### TECHNICAL FIELD

The present disclosure relates to a field of display technologies, and in particular, to a light-emitting device and a preparation method therefor, and a display apparatus.

### BACKGROUND

Light-emitting devices refer to devices made according to the photoelectric effect, which have a wide range of applications in new energy, sensing, communication, display, lighting and other fields, such as solar cells, photodetectors, organic light-emitting diodes (OLED) or quantum dot light-emitting diodes (QLED).

Quantum dots (QDs) are semiconductor clusters with size ranging from 1 to 10 nm, which have photoelectronic properties with tunable band gap due to quantum size effect, and can be applied in light-emitting diodes, solar cells, biofluorescent labeling and other fields. Compared with traditional liquid crystal displays (LCDs), QLED displays have the advantages of simple structure, low power consumption, short response time, high contrast ratio, and wide viewing angle. Similar to conventional light-emitting diodes (LEDs), QLEDs typically have a p-i-n structure including an anode, a hole-transport layer (HTL), a light-emitting layer (EML), an electron-transport layer (ETL), and a cathode. Under forward bias, electrons and holes are injected from opposite electrodes and passed through a transport layer to the light-emitting layer, and the injected carriers in the quantum dots generate photons through radiative transitions.

A key indicator of QLED improvement is the efficiency of the device at regular use luminuance (around 500 nit). Although the maximum current efficiency that QLED can achieve at present basically meets the standard, the efficiency under conventional luminuance is very low, often only half or even lower of the maximum efficiency.

Therefore, how to greatly improve the efficiency of QLED under conventional luminuance while maintaining good efficiency and lifespan has become an urgent problem for the industry.

### SUMMARY

Therefore, the present disclosure provides a light-emitting device and a preparation method therefor, and a display apparatus.

The present disclosure provides a light-emitting device, the light-emitting device includes an anode, a hole transport layer made of a first hole transport material, a light-emitting layer made of a light-emitting material, and a cathode; wherein a difference value between a conduction band energy level of the light-emitting material and a valence band energy level of the first hole transport material is a first difference value, a difference value between the valence band energy level of the first hole transport material and a valence band energy level of the light-emitting material is a second difference value; wherein the first difference value is greater than twice the second difference value.

Alternatively, in some embodiments of the present disclosure, a thickness of the light-emitting layer is greater than or equal to 10 nm.

Alternatively, in some embodiments of the present disclosure, the thickness of the light-emitting layer ranges from 10 nm to 200 nm.

Alternatively, in some embodiments of the present disclosure, the light-emitting material is selected from one or more of a single structure quantum dot and a core-shell structure quantum dot, the single structure quantum dot is selected from one or more of a group II-VI compound, a group III-V compound, and a group I-III-VI compound, the group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe and CdZnSTe, the group III-V compound is selected from one or more of InP, InAs, GaP, GaAs, GaSb, AlN, AlP, InAsP, InNP, InNSb, GaAlNP and InAINP, the group I-III-VI compound is selected from one or more of CuInS₂, CuInSe₂ and AgInSe₂, the core of the core-shell structure quantum dot is selected from any one of the single structure quantum dots, and the shell material of the core-shell structure quantum dot is selected from one or more of CdS, CdTe, CdSeTe, CdZnSe, CdZnS, CdSeS, ZnSe, ZnSeS and ZnS.

Alternatively, in some embodiments of the present disclosure, the first hole transport material is selected from one or more of TFB, PVK, poly-TPD, TCATA, CBP, TPD, NPB, PEDOT: PSS, TAPC, doped graphene, undoped graphene, and C60, or the first hole transport material is selected from one or more of doped or undoped NiO, MoOx, WOx and CuO.

Alternatively, in some embodiments of the present disclosure, a thickness of the hole transport layer ranges from 10 nm to 100 nm.

Alternatively, in some embodiments of the present disclosure, the light-emitting device further includes a hole injection layer disposed between the hole transport layer and the anode; and/or, a material of the hole injection layer is selected from one or more of PEDOT: PSS, MCC, CuPc, F4-TCNQ, HATCN, a transition metal oxide and a transition metal chalcogenide compound.

Alternatively, in some embodiments of the present disclosure, the light-emitting device further includes an electron transport layer disposed between the light-emitting layer and the cathode; and/or, a material of the electron transport layer is selected from one or more of nano-zinc oxide, nano-titanium oxide, nano-tin oxide, nano-barium titanate and element-doped nano-oxide electron transport materials thereof, and a doping element is selected from one or more of aluminum element, magnesium element, lithium element, manganese element, yttrium element, lanthanum element, copper element, nickel element, zirconium element, cerium element, and gadolinium element.

Alternatively, in some embodiments of the present disclosure, a material of the anode is selected from one or more of a metal, a carbon material, and a metal oxide, the metal is selected from one or more of Al, Ag, Cu, Mo, Au, Ba, Ca and Mg; the carbon material is selected from one or more of graphite, carbon nanotubes, graphene, and carbon fibers; the metal oxide includes doped or undoped metal oxides, including one or more of ITO, FTO, ATO, AZO, GZO, IZO, MZO and AMO, or includes composite electrodes with metal sandwiched between doped or undoped transparent metal oxides, and the composite electrodes are selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂ and TiO₂/Al/TiO₂.

Alternatively, in some embodiments of the present disclosure, a material of the cathode is selected from one or more of a metal, a carbon material, and a metal oxide, the metal is selected from one or more of Al, Ag, Cu, Mo, Au, Ba, Ca and Mg; the carbon material is selected from one or more of graphite, carbon nanotubes, graphene, and carbon fibers; the metal oxide includes doped or undoped metal oxides, including one or more of ITO, FTO, ATO, AZO, GZO, IZO, MZO and AMO, or includes composite electrodes with metal sandwiched between doped or undoped transparent metal oxides, and the composite electrodes are selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂ and TiO₂/Al/TiO₂.

Correspondingly, an embodiment of the present disclosure further provides a method for preparing a light-emitting device, wherein the method includes the following steps:
providing an anode;
stacking a hole transport layer, a light-emitting layer, and a cathode on the anode;
or,
providing a cathode;
stacking a light-emitting layer, a hole transport layer, and an anode on the cathode;
wherein the light-emitting layer is made of a light-emitting material, and the hole transport layer is made of a first hole transport material; a difference value between a conduction band energy level of the light-emitting material and a valence band energy level of the first hole transport material is a first difference value; a difference value between the valence band energy level of the first hole transport material and a valence band energy level of the light-emitting material is a second difference value; wherein the first difference value is greater than twice the second difference value.

Alternatively, in some embodiments of the present disclosure, the light-emitting device further includes a hole injection layer, and the step of stacking the hole transport layer, the light-emitting layer, and the cathode on the anode includes: stacking the hole injection layer, the hole transport layer, the light-emitting layer, and the cathode on the anode;
or,
the light-emitting device further includes a hole injection layer, and the step of stacking the light-emitting layer, the hole transport layer, and the anode on the cathode includes stacking the light-emitting layer, the hole transport layer, the hole injection layer, and the anode on the cathode.

Alternatively, in some embodiments of the present disclosure, the light-emitting device further includes an electron transport layer, and the step of stacking the hole injection layer, the hole transport layer, the light-emitting layer, and the cathode on the anode includes: stacking the hole injection layer, the hole transport layer, the light-emitting layer, the electron transport layer, and the cathode on the anode;

or,

the light-emitting device further includes an electron transport layer, and the step of stacking the light-emitting layer, the hole transport layer, the hole injection layer, and the anode on the cathode includes stacking the electron transport layer, the light-emitting layer, the hole transport layer, the hole injection layer, and the anode on the cathode.

Alternatively, in some embodiments of the present disclosure, a thickness of the light-emitting layer is greater than or equal to 10 nm.

Alternatively, in some embodiments of the present disclosure, the thickness of the light-emitting layer ranges from 10 nm to 200 nm.

Correspondingly, an embodiment of the present disclosure further provides a display apparatus. The display apparatus includes the light-emitting device as described above.

### BRIEF DESCRIPTION OF THE DRAWINGS

In order to illustrate the technical solutions of the present disclosure clearly, the following will briefly describe the accompanying drawings involved in the description of embodiments. It will be apparent that the drawings in the following description are merely some of the embodiments of the present disclosure, and other drawings may be obtained by those skilled in the art without involving any inventive effort based on these drawings.

FIG. 1 is a JVL graph between current efficiency and luminuance of a light emitting device according to an embodiment of the present disclosure.

FIG. 2 is a schematic diagram of the migration trajectory of carriers during operation of the light-emitting device according to an embodiment of the present disclosure.

FIG. 3 is a schematic diagram of the light-emitting device according to an embodiment of the present disclosure.

FIG. 4 is a schematic diagram of another light-emitting device according to an embodiment of the present disclosure.

FIG. 5 is a flowchart of a method for preparing the light-emitting device according to an embodiment of the present disclosure.

FIG. 6 is a flowchart of another method for preparing the light-emitting device according to an embodiment of the present disclosure.

FIG. 7 is a graph comparing JVL curves between current density and voltage of the light-emitting device according to Example 1 and Comparative Example 1 of the present disclosure.

FIG. 8 is a graph comparing JVL curves between current efficiency and luminuance of the light-emitting device according to Example 2 and Comparative Example 3 of the present disclosure.

FIG. 9 is a graph comparing JVL curves between current efficiency and luminuance of the light-emitting device according to Example 1, Comparative Example 1 and Comparative Example 2 of the present disclosure.

FIG. 10 is a schematic diagram of a display apparatus according to an embodiment of the present disclosure.

### EMBODIMENTS OF THE PRESENT DISCLOSURE

The technical solutions in the present disclosure will be fully and clearly described with reference to the accompanying drawings. It is apparent that the described embodiments are only a part of the embodiments of the present disclosure, rather than all of the embodiments. Based on the embodiments in the present disclosure, all other embodiments obtained by a person skilled in the art without involving any inventive effort fall within the scope of the present disclosure.

It should be noted that the order of description of the following embodiments is not intended as a limitation of the preferred order of the embodiments. In addition, in the description of the present disclosure, the term “includes” means “includes but is not limited to”.

Various embodiments of the present disclosure may exist in the form of a range. It should be understood that the description in range format is merely for convenience and brevity, and should not be construed as a rigid restrictions on the scope of the present disclosure. Therefore, it should be considered that the range description has specifically disclosed all possible sub-ranges as well as a single value within the range. For example, it should be considered that the range description from 1 to 6 has specifically disclosed sub-ranges, such as from 1 to 3, from 1 to 4, from 1 to 5, from 2 to 4, from 2 to 6, from 3 to 6, and the like, and single numbers within the ranges, such as 1, 2, 3, 4, 5, and 6, which apply regardless of the range. In addition, whenever a numeric range is indicated herein, it includes any referenced number (fraction or integer) within the referenced range. In addition, whenever a numerical range is indicated herein, it is meant to include any referenced number (fraction or integer) within the indicated range.

In the present disclosure, “one or more” means one or more, and “more” means two or more. “One or more”, “at least one of the following” or similar expressions refer to any combination of these items, including any combination of single items (items) or complex items (items).For example, “at least one of a, b, or c”, or “at least one of a, b, and c”, can mean: a, b, c, a-b (i.e. a and b), a-c, b-c, or a-b-c, among them, a, b, c can be single or multiple, respectively.

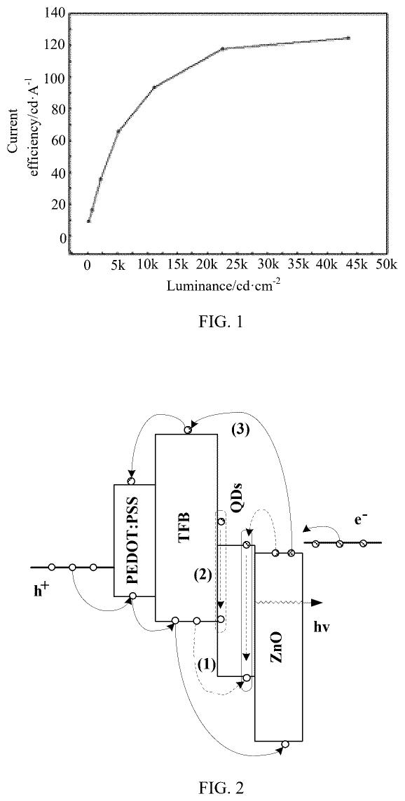

Most of the current research on QLED mainly involves how to improve the current efficiency (CE) of a device and prolong the life of the device. However, the applicant found in actual research that the current efficiency (CE) of the device is not a stable state. If the luminuance of the device is used as the abscissa and the current efficiency of the device is used as the ordinate to draw, the presented state is generally shown in FIG. 1.

In FIG. 1, it may be found that the efficiency of the device will increase with the increase of the luminuance of the device in a wide range. In this case, although the maximum current efficiency (CE_max) of the device has performed quite well, its corresponding current efficiency at conventional luminuance (about 500 nit) is very low and cannot meet the needs of QLED for daily use.

In order to solve this problem, the applicant has discovered through research that FIG. 2 is a schematic diagram of the migration trajectory of carriers during the operation of QLED devices. In FIG. 2, the current flowing into the device ultimately produces three effects:
(1) the carriers recombine in a light-emitting layer to generate light, which is referred to as effect I₍₁₎;
(2) the carrier recombines with the conduction band of the light-emitting layer through the valence band of a hole transport layer to generate unnecessary electromagnetic waves, which is referred to as effect I₍₂₎;
(3) electrons tunnel through a quantum dot layer and are lost as thermal energy in the device, which is recorded as effect I₍₃₎.

When the luminuance of the device is large, the driving voltage is high, and the effect I₍₁₎ is dominant at this time, so the current efficiency is high. Under conventional luminuance (about 500 nit), the driving voltage is low. At this time, the proportion of effect I₍₂₎ increases, resulting in low current efficiency.

Based on this, in the light-emitting device, the present disclosure limits the energy level matching of materials of the hole transport layer and the light-emitting layer, and controls a difference value between a conduction band energy level of the light-emitting layer and a valence band energy level of a first hole transport material of the hole transport layer to be greater than twice a difference value between the valence band energy level of the first hole transport material of the hole transport layer and a valence band energy level of a light-emitting material of the light-emitting layer. In this way, the following effects can be achieved: on the premise that the light-emitting device may maintain good efficiency and life, the efficiency of the light-emitting device under conventional luminuance is greatly improved, the performance of the light-emitting device is more in line with commercial application standards, and the goal of applying quantum dot electroluminescence technology to the display industry is further advanced.

In order to facilitate the understanding of the above inventive concept of the present disclosure, the above inventive concept of the present disclosure will be described in more detail below with reference to the accompanying drawings and specific embodiments.

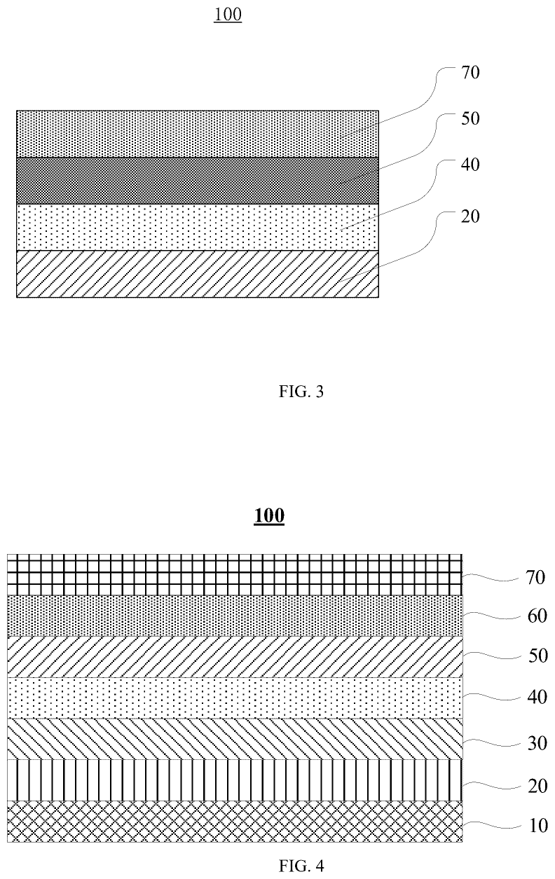

In one embodiment, as shown in FIG. 3, the present disclosure provides a light-emitting device 100 including an anode 20, a hole transport layer 40, a light-emitting layer 50, and a cathode 70 stacked in order.

A material of the light-emitting layer 50 includes a light-emitting material, and a material of the hole transport layer 40 includes a first hole transport material. A difference value between a conduction band energy level CB_{QD} of the light-emitting material and a valence band energy level VB_{HT} of the first hole transport material is a first difference value; a difference value between the valence band energy level VB_{HT} of the first hole transport material and a valence band energy level VB_{QD} of the light-emitting material is a second difference value. The first difference value is greater than twice the second difference value, that is, the difference value between the conduction band energy level CB_{QD} of the light-emitting material and the valence band energy level VB_{HT} of the first hole transport material is greater than twice the difference value between the valence band energy level VB_{HT} of the first hole transport material and the valence band energy level VB_{QD} of the light-emitting material, as expressed in the following formula: (CB_{QD}−VB_{HT})>2(VB_{HT}−VB_{QD}).

In this embodiment, by limiting the energy level matching of the materials of the hole transport layer and the light-emitting layer on the conventional light-emitting device to satisfy the condition that the difference value between the conduction band energy level of the light-emitting material of the light-emitting layer and the valence band energy level of the first hole transport material of the hole transport layer is greater than twice the difference value between the valence band energy level of the first hole transport material of the hole transport layer and the valence band energy level of the light-emitting material of the light-emitting layer, the following effects may be achieved: on the premise of maintaining the good efficiency and life of the light-emitting device, the recombination of carriers in the non-light-emitting region may be suppressed, the leakage current of the device may be suppressed, the current efficiency of the device at low current may be improved, the efficiency of the light-emitting device at conventional luminuance (about 500 nit) may be greatly improved, the performance of the light-emitting device is more in line with commercial application standards, and the goal of applying the quantum dot electroluminescence technology to the display industry may be further improved.

In the present embodiment, the conduction band energy level CB_{QD} and the valence band energy level VB_{HT} represent a bottom energy level of the conduction band and a top energy level of the valence band, respectively. The bottom energy level of the conduction band is a potential energy of the electron, and the top energy level of the valence band is the highest energy of the electron at absolute zero. Between the bottom energy level of the conduction band and the top energy level of the valence band is an energy band gap of a semiconductor material.

As shown in FIG. 2, in the schematic diagram of the migration trajectory of carriers during the operation of the QLED device, the current flowing into the device finally produces three effects: (1) the carriers recombine in the light-emitting layer to generate light, which is referred to as effect I₍₁₎; (2) the carrier recombines with the conduction band of the light-emitting layer through the valence band of a hole transport layer to generate unwanted electromagnetic waves, which is referred to as effect I₍₂₎; (3) electrons tunnel through a quantum dot layer and are lost as thermal energy in the device, which is recorded as effect I₍₃₎. When the luminuance of the device is large, the driving voltage is high, and the effect I₍₁₎ is dominant at this time, so the current efficiency is high. Under conventional luminuance (about 500 nit), the driving voltage is low. At this time, the proportion of effect I₍₂₎ increases, resulting in low current efficiency. Improving the efficiency of the device under conventional luminuance actually means increasing the proportion of I₍₁₎ and reducing the proportion of I₍₂₎. The “CB_{QD}−VB_{HT}” represents a minimum energy required for I₍₂₎ to occur. The larger the “CB_{QD}−VB_{HT}”, the less likely I₍₂₎ to occur; the “VB_{HT}−VB_{QD}” represents a minimum energy required for holes at the top of a valence band of the hole transport layer to migrate to the light-emitting layer. The smaller the “VB_{HT}−VB_{QD}”, the easier the holes at the top of the valence band of the hole transport layer will migrate to the light-emitting layer, which is more conducive to the occurrence of I₍₁₎. Therefore, when the condition “CB_{QD}−VB_{HT}>2 (VB_{HT}−VB_{QD})” is satisfied, I₍₁₎ dominates, and at this time the current efficiency increases.

In the present embodiment, the light-emitting layer (EML) 50 is located on the side of the hole transport layer (HTL) 40 away from the anode 20, and the light-emitting material of the light-emitting layer 50 is a quantum dot, for example, one of a red quantum dot, a green quantum dot and a blue quantum dot. The quantum dot may be selected from, but is not limited to, one or more of a single structure quantum dot and a core-shell structure quantum dot. For example, the quantum dot may be selected from, but are not limited to, one or more of a group II-VI compound, a group III-V compound, and a group I-III-VI compound, the group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe and CdZnSTe, the group III-V compound is selected from one or more of InP, InAs, GaP, GaAs, GaSb, AlN, AlP, InAsP, InNP, InNSb, GaAlNP and InAlNP, the group I-III-VI compound is selected from one or more of CuInS₂, CuInSe₂ and AgInSe₂;

the core of the core-shell structure quantum dot is selected from any one of the single structure quantum dots, and the shell material of the core-shell structure quantum dot is selected from one or more of CdS, CdTe, CdSeTe, CdZnSe, CdZnS, CdSeS, ZnSe, ZnSeS and ZnS.

In one embodiment, a thickness of the light-emitting layer 50 is greater than or equal to 10 nm, specifically ranging between 10 nm and 200 nm, which may effectively prevent electrons from tunneling through the electron dot layer and loss of thermal energy in the device (that is, the above-mentioned effect I₍₃₎), and at the same time, it is necessary for electrons to migrate to the interface between the light-emitting layer 50 and the hole transport layer 40 to recombine, because the mobility of the light-emitting layer 50 is low, appropriately increasing the thickness of the light-emitting layer 50 may also effectively suppress the recombination of carriers through the valence band of the hole transport layer and the conduction band of the light-emitting layer 50 to generate unnecessary electromagnetic waves (that is, the above-mentioned effect I₍₂₎).

In this embodiment, by limiting the thickness of the light-emitting layer to be greater than or equal to 10 nm and limiting the energy level matching of the first hole transport material of the hole transport layer and the light-emitting material of the light-emitting layer to satisfy the condition that the difference value between the conduction band energy level of the light-emitting material of the light-emitting layer and the valence band energy level of the the material of the hole transport layer is greater than twice the difference value between the valence band energy level of the first hole transport material of the hole transport layer and the valence band energy level of the light-emitting material of the light-emitting layer, the following effects may be achieved: on the premise of maintaining the good efficiency and life of the light-emitting device, the recombination of carriers in the non-light-emitting region may be suppressed, the leakage current of the device may be suppressed, the current efficiency of the device at low current may be improved, the efficiency of the light-emitting device at conventional luminuance (about 500 nit) may be greatly improved, and the performance of the light-emitting device is more in line with commercial application standards.

In one embodiment, the difference value between the conduction band energy level CB_{QD} of the light-emitting material of the light-emitting layer and the valence band energy level VBur of the first hole transport material of the hole transport layer is greater than the difference value between the valence band energy level VB_{HT} of the first hole transport material of the hole transport layer and the valence band energy level VB_{QD} of the light-emitting material of the light-emitting layer, that is, as expressed in the following formula (1):

CB_{QD}−VB_{HT}>2 (VB_{HT}−VB_{QD}) (1)

When the energy level matching of the first hole transport material of the hole transport layer and the light-emitting material of the light-emitting layer does not conform to the above formula (1), the proportion of unnecessary electromagnetic waves generated by recombination of carriers through the valence band of the first hole transport material of the hole transport layer and the conduction band of the light-emitting material of the light-emitting layer (that is, the above-mentioned effect I₍₂₎) is large, which affects CE_500 nit, and even causes CE_max to fail to meet the standard in severe cases. The data of the energy band energy level of a selected light-emitting material of the light-emitting layer and the first hole transport material of the hole transport layer can be substituted into the preset energy level matching condition to perform matching calculation, and the matching of different materials can be accomplished.

In this embodiment, the first hole transport material of the hole transport layer 40 may be selected from organic materials having hole transport capabilities, including, but not limited to, one or more of poly(9, 9-dioctylfluorene-CO-N-(4-butylphenyl) diphenylamine) (TFB), Poly(N-vinyl carbazole) (PVK), Poly [N,N′-bis(4-butylphenyl)-N,N′-bis(phenyl)-benzi (poly-TPD), poly(9,9-dioctylfluorene-co-bis-N, N ‘-bis(phenyl) benzidine) (PFB), 4,4’,4″-Tris (carbazol-9-yl)-triphenylamine (TCATA), 4,4′-Bis(N-carbazolyl)-1,1′-biphenyl (CBP), N,N′-Bis(3-methylphenyl)-N,N′-bis(phenyl)benzidine(TPD), N,N′-Bis-(1-naphthalenyl)-N,N′-bis-phenyl-(1,1′-biphenyl)-4,4′-diamine (NPB), Poly(3,4-ethylenedioxythiophene)-poly(styrenesulfonate)dry re-dispersiblepellets] (PEDOT:PSS), 4,4′-cyclohexylidenebis[N,N-bis(p-tolyl)aniline] (TAPC), doped graphene, undoped graphene, and C60. The material of the hole transport layer 40 may also be selected from inorganic materials having hole transport capabilities, including, but not limited to, one or more of doped or undoped NiO, MoOₓ, WOₓ, and CuO. The thickness of the hole transport layer 40 may be, for example, range from 10 nm to 100 nm, such as 10 nm, 20 nm, 30 nm, 40 nm, 50 nm, 60 nm, 100 nm, or the like.

In this embodiment, when the energy level matching of the first hole transport material of the hole transport layer and the light-emitting material of the light-emitting layer meet the condition that the difference value between the conduction band energy level of the light-emitting material of the light-emitting layer and the valence band energy level of the first hole transport material of the hole transport layer is greater than twice the difference value between the valence band energy level of the first hole transport material of the hole transport layer and the valence band energy level of the light-emitting material of the light-emitting layer, the following effects may be achieved: on the premise of maintaining the good efficiency and life of the light-emitting device, the recombination of carriers in the non-light-emitting region may be suppressed, the leakage current of the device may be suppressed, the current efficiency of the device at low current may be improved, and the efficiency of the light-emitting device at conventional luminuance (about 500 nit) may be greatly improved.

Referring to FIG. 3, the anode 20 is stacked on a glass substrate 10.

A material of the glass substrate 10 is a material known in the art for use in a substrate, such as a transparent conductive oxide material selected from one or more of indium tin oxide (ITO), indium zinc oxide (IZO), zinc oxide (ZnO) and indium tin zinc oxide (ITZO).

The anode 20 may be selected from one or more of a metal, a carbon material, and a metal oxide, the metal may be, for example, one or more of Al, Ag, Cu, Mo, Au, Ba, Ca and Mg; the carbon material may be, for example, one or more of graphite, carbon nanotubes, graphene and carbon fibers; the metal oxide may be doped or undoped metal oxides, including one or more of ITO, FTO, ATO, AZO, GZO, IZO, MZO and AMO, or includes composite electrodes with metal sandwiched between doped or undoped transparent metal oxides, and the composite electrodes are selected from, but not limited to, one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂ and TiO₂/Al/TiO₂. A thickness of the anode 20 is an anode thickness known in the art, and may be, for example, range from 10 nm to 200 nm, such as 10 nm, 50 nm, 80 nm, 100 nm, 120 nm, 150 nm, 200 nm, or the like.

Referring further to FIG. 4, in one embodiment, the light-emitting device 100 further includes a hole injection layer (HIL) 30. The hole injection layer 30 is located between the hole transport layer 40 and the anode 20. A material of the hole injection layer 30 may be selected from materials having hole injection capabilities, including, but not limited to, one or more of PEDOT: PSS, MCC, CuPc, F4-TCNQ, HATCN, transition metal oxides, and transition metal chalcogenides. PEDOT: PSS is a high molecular polymer whose Chinese name is poly(3, 4-ethylenedioxythiophene)-poly (styrenesulfonic acid). A thickness of the hole injection layer 30 may be, for example, range from 10 nm to 100 nm, such as 10 nm, 20 nm, 30 nm, 40 nm, 50 nm, 60 nm, 100 nm, or the like.

Referring further to FIG. 4, in one embodiment, the light-emitting device 100 further includes an electron transport layer (ETL) 60. The electron transport layer 60 is located between the light-emitting layer 50 and the cathode 70, wherein the electron transport layer 60 may adopt conventional nano-oxide electron transport materials in the art, including but not limited to the following materials: nano-zinc oxide, nano-titanium oxide, nano-tin oxide, nano-barium titanate, or the like, and their corresponding elements doped with nano-oxide electron transport materials, and the doping elements include but not limited to the following elements: aluminum, magnesium, lithium, manganese, yttrium, lanthanum, copper, nickel, zirconium, cerium, gadolinium, or the like.

Referring further to FIG. 4, in one embodiment, the cathode 70 is disposed over the electron transport layer 60. A material of the cathode 70 may be selected from one or more of a metal, a carbon material, and a metal oxide, the metal may be, for example, one or more of Al, Ag, Cu, Mo, Au, Ba, Ca and Mg; the carbon material may be, for example, one or more of graphite, carbon nanotubes, graphene, and carbon fibers; the metal oxide may be doped or undoped metal oxides, including one or more of ITO, FTO, ATO, AZO, GZO, IZO, MZO and AMO, or includes composite electrodes with metal sandwiched between doped or undoped transparent metal oxides, and the composite electrodes are selected from, but not limited to, one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂. A thickness of the cathode 70 is a cathode thickness known in the art, and may be, for example, range from 10 nm to 200 nm, such as 10 nm, 35 nm, 50 nm, 80 nm, 120 nm, 150 nm, 200 nm, or the like.

It may be understood that in addition to the above functional layers, the light-emitting device 100 may also include some functional layers conventionally used for light-emitting devices that contribute to improving the performance of the light-emitting devices, such as an electron blocking layer, a hole blocking layer, an electron injection layer, an interface modification layer and the like. It may be understood that the material and thickness of each layer of the light-emitting device 100 can be adjusted according to the light-emitting requirements of the light-emitting device 100.

Based on the same concept, the present disclosure also provides a method for preparing a light-emitting device 100.

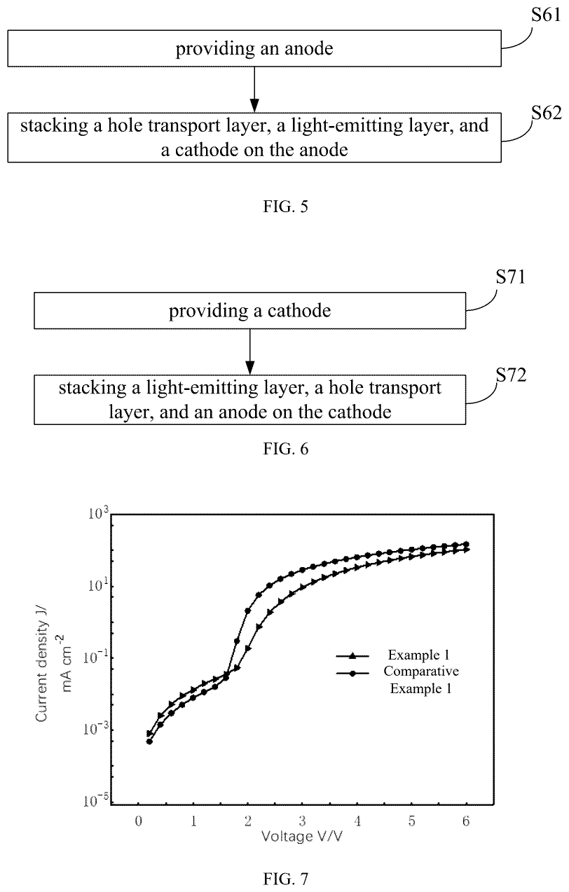

In one embodiment, as shown in FIG. 5, the light-emitting device 100 is an upright quantum dot light-emitting diode, and the method for preparing the light-emitting device 100 specifically includes the following steps:

Step S61: providing an anode.

In this embodiment, the substrate is an ITO (Indium-Tin Oxide) substrate, and the substrate of the ITO substrate needs to undergo a pretreatment process. The specific pretreatment steps include: cleaning an ITO conductive glass with a detergent to initially remove the stains on the surface, then ultrasonic cleaning in deionized water, isopropyl alcohol, acetone and deionized water in turn to remove the impurities on the surface, and finally blowing drying with high-purity nitrogen to obtain an ITO anode.

Step S62: stacking a hole transport layer, a light-emitting layer, and a cathode on the anode.

A material of the light-emitting layer includes a light-emitting material, and a material of the hole transport layer includes a first hole transport material. A difference value between a conduction band energy level of the light-emitting material and a valence band energy level of the first hole transport material is a first difference value. A difference value between the valence band energy level of the first hole transport material and a valence band energy level of the light-emitting material is a second difference value. The first difference value is greater than twice the second difference value. That is, the difference value between the conduction band energy level of the light-emitting material and the valence band energy level of the first hole transport material is greater than twice the difference value between the valence band energy level of the first hole transport material and the valence band energy level of the light-emitting material; a thickness of the light-emitting layer is greater than or equal to 10 nm.

It may be understood that when the light-emitting device further includes a hole injection layer, step S62 is to stack the hole injection layer, the hole transport layer, the light-emitting layer, and the cathode on the anode. Further, when the light-emitting device further includes an electron transport layer, step S62 is to stack the hole injection layer, the hole transport layer, the light-emitting layer, the electron transport layer, and the cathode on the anode. Specifically, it includes:

In step S621, forming the hole injection layer on a substrate of an anode substrate.

The ITO substrate is placed on a glue homogenizer, and a prepared solution of a hole injection material is spin-coated to form a film. A thickness of the film is controlled by adjusting the concentration of a solution, a spin-coating speed and a spin-coating time, and then the hole injection layer is obtained by thermal annealing at an appropriate temperature.

In step S622, forming the hole transport layer on the hole injection layer.

The ITO substrate is placed on the glue homogenizer, and a prepared solution of a hole transport material is spin-coated to form a film. The thickness of the film is controlled by adjusting the concentration of a solution, the spin-coating speed and the spin-coating time, and then the hole transport layer is obtained by thermal annealing at an appropriate temperature.

In step S623, forming the light-emitting layer on the hole transport layer.

Specifically, a substrate of a spin-coated hole transport layer is placed on the glue homogenizer, a solution of the light-emitting material prepared with a preset concentration is spin-coated to form a film, and the thickness of the light-emitting layer is controlled by adjusting the concentration of the solution, the spin-coating speed and the spin-coating time, about 20 to 60 nm, and the light-emitting layer is dried at an appropriate temperature.

In step S624, forming the electron transport layer on the light-emitting layer.

Formulating an electron transport material into a solution of a preset concentration;

A substrate on which the light-emitting layer has been spin-coated is placed on the glue homogenizer, a solution of the electron transport material prepared with the preset concentration is spin-coated to form a film respectively, the thickness of each of electron transport layers is controlled by adjusting the concentration of the solution and the spin-coating speed, and the thickness is 20-60 nm, and then the film is annealed to form the film respectively to obtain the electron transport layer.

In step S625, forming the cathode on the electron transport layer.

A substrate on which each of functional layers has been deposited is placed in an evaporation chamber and a layer of 40-80 nm cathode material is thermally evaporated through a mask plate as the cathode.

It may be understood that the method of preparing the light-emitting device may further include a packaging step, a packaging material may be acrylic resin or epoxy resin, the packaging may be machine packaging or manual packaging, and ultraviolet curing glue sealing may be adopted, and the concentrations of oxygen and water in the environment where the packaging step is performed are both lower than 0.1 ppm to ensure the stability of the light-emitting device.

In one embodiment, as shown in FIG. 6, the light-emitting device 100 is an inverted quantum dot light-emitting diode, and the method for preparing the light-emitting device 100 specifically includes the following steps:
step S71: providing a cathode;
step S72: stacking a light-emitting layer, a hole transport layer, and an anode on the cathode.

The material of the light-emitting layer includes the light-emitting material, and the material of the hole transport layer includes the first hole transport material; the difference value between the conduction band energy level of the light-emitting material and the valence band energy level of the first hole transport material is the first difference value; the difference value between the valence band energy level of the first hole transport material and the valence band energy level of the light-emitting material is the second difference value; wherein, the first difference value is greater than twice the second difference value; that is, the difference value between the conduction band energy level of the light-emitting material and the valence band energy level of the first hole transport material is greater than twice the difference value between the valence band energy level of the first hole transport material and the valence band energy level of the light-emitting material; the thickness of the light-emitting layer is greater than or equal to 10 nm.

It may be understood that when the light-emitting device further includes the electron transport layer, step S72 is to stack the electron transport layer, the light-emitting layer, the hole transport layer, and the anode on the cathode. Further, when the light-emitting device further includes the hole injection layer, step S72 is to stack the electron transport layer, the light-emitting layer, the hole transport layer, the hole injection layer, and the anode on the cathode.

It may be understood that when the light-emitting device further includes other functional layers such as the electron blocking layer, the hole blocking layer, the electron injection layer, and/or the interface modification layer, the method for preparing the light-emitting device further includes steps of forming each of functional layers.

It should be noted that the anode 20, the light-emitting layer 50, the cathode 70, and other functional layers in the present disclosure can be prepared by conventional techniques in the art, including but not limited to solution methods and deposition methods, wherein solution methods include but not limited to spin coating, coating, inkjet printing, scraping coating, dipping and pulling, soaking, spraying, roller coating, or casting; deposition methods include chemical methods and physical methods, wherein chemical methods include but not limited to chemical vapor deposition methods, continuous ion layer adsorption and reaction methods, anodic oxidation methods, electrolytic deposition methods, or co-precipitation methods, and physical methods include but not limited to thermal evaporation coating methods, electron beam evaporation coating methods, magnetron sputtering methods, multi-arc ion coating methods, physical vapor deposition methods, atomic layer deposition methods, or pulsed laser deposition methods. When the anode 20, the light-emitting layer 50, the cathode 70, and other functional layers are prepared by solution methods, a drying treatment step needs to be added.

It may be understood that the method of preparing the light-emitting device may further include the packaging step, the packaging material may be acrylic resin or epoxy resin, the packaging may be machine packaging or manual packaging, and ultraviolet curing glue sealing may be adopted, and the concentrations of oxygen and water in the environment where the packaging step is performed are both lower than 0.1 ppm to ensure the stability of the light-emitting device.

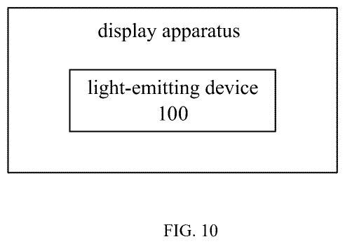

Based on the same concept, in one embodiment, as shown in FIG. 10, the present disclosure further provides a display apparatus including the light-emitting device 100 described in any of the above embodiments.

In this embodiment, the light-emitting device 100 is the same as the light-emitting device 100 described in any of the above embodiments, and specific structures and functions can be referred to with reference to the light-emitting device 100 described in any of the above embodiments, and will not be repeatedly described herein.

In the present embodiment, the display apparatus may be any electronic product having a display function, and the electronic product includes, but is not limited to, a smartphone, a tablet computer, a laptop computer, a digital camera, a digital video camera, a smart wearable device, a smart weighing scale, a vehicle display, a television, or an e-book reader, and the smart wearable device may be, for example, a smart bracelet, a smart watch, a Virtual Reality (VR) helmet, or the like.

In this embodiment, the display apparatus includes a light-emitting device 100. By limiting the thickness of the light-emitting layer to be greater than or equal to 10 nm in the conventional light-emitting device structure and limiting the energy level matching of the first hole transport material of the hole transport layer and the light-emitting material of the light-emitting layer to satisfy the condition that the difference value between the conduction band energy level of the light-emitting material of the light-emitting layer and the valence band energy level of the first hole transport material of the hole transport layer is greater than twice the difference value between the valence band energy level of the first hole transport material of the hole transport layer and the valence band energy level of the light-emitting material of the light-emitting layer, the following effects may be achieved: on the premise of maintaining the good efficiency and life of the light-emitting device, the recombination of carriers in the non-light-emitting region may be suppressed, the leakage current of the device may be suppressed, the current efficiency of the device at low current may be improved, the efficiency of the light-emitting device at conventional luminuance (about 500 nit) may be greatly improved, the performance of the light-emitting device is more in line with commercial application standards, and the goal of applying the quantum dot electroluminescence technology to the display industry may be further improved.

Hereinafter, the technical solutions and technical effects of the present disclosure will be described in detail with reference to specific examples, comparative examples, and experimental examples, and the following examples are merely partial examples of the present disclosure, and do not specifically limit the present disclosure.

### Example 1

A structure of a light-emitting device (QLED device) was anode (ITO)//hole injection layer (PEDOT: PSS)//hole transport layer TFB//light-emitting layers (QDs)/electron transport layer (ZnO)/cathode (Al). Among them, the QDs materials were core-shell structured green quantum dots with component CdSe/ZnS, and the thickness was 10 nm.

The core-shell structure green quantum dots of CdSe/ZnS had a position of −3.8 eV for conduction band level CB_{QD} and a position of −6.1 eV for valence band level VBQD. The position of the valence band level VB_{HT} of TFB was −5.4 eV. CB_{QD}−VB_{HT}=1.6 eV, 2 (VB_{HT}−VB_{QD})=1.4 eV, CB_{QD}−VB_{HT}>2 (VB_{HT}−VB_{QD}).

### Comparative Example 1

The light-emitting layer was different from Example 1 in that the thickness of the light-emitting layer was 8 nm.

### Comparative Example 2

The difference from Example 1 was that the material of the hole transport layer was changed from TFB to Poly-TPD. The core-shell structure green quantum dots of CdSe/ZnS had a position of −3.8 eV for conduction band level CB_{QD} and a position of −6.1 eV for valence band level VB_{QD}. The position of the valence band level VB_{HT} of Poly-TPD was −5.1 eV. CB_{QD}−VB_{HT} =1.3 eV, 2 (VB_{HT}−VB_{QD}) =1.4 eV, CB_{QD}−VB_{HT}<2 (VB_{HT}−VB_{QD})

### Example 2

The difference from Example 1 was that the device structure of the QLED device was ITO//PEDOT: PSS//PVK//QDs//ZnO//Al, the quantum dot material were core-shell structure blue quantum dots of CdSe/ZnS, the thickness was 15 nm, and the hole transport layer was changed from TFB to PVK. The core-shell structure blue quantum dots of CdSe/ZnS had a position of −3.5 eV for conduction band level CB_{QD} and a position of −6.5 eV for valence band level VB_{QD}. The position of the valence band level VB_{HT} of PVK was −5.8 eV. CB_{QD}−VB_{HT}=2.3 eV, 2 (VB_{HT}−VB_{QD})=1.4 eV, CB_{QD}−VB_{HT}>2 (VB_{HT}−VB_{QD}).

### Comparative Example 3

The difference from Example 2 was that the material of the hole transport layer was changed from PVK to TFB. The core-shell structure blue quantum dots of CdSe/ZnS had a position of −3.5 eV for conduction band level CB_{QD} and a position of −6.5 eV for valence band level VB_{QD}. The position of the valence band level VB_{HT} of TFB was −5.4 eV. CB_{QD}−VB_{HT}=2 eV, 2 (VB_{HT}−VB_{QD})=2.2 eV, CB_{QD}−VB_{HT}<2 (VB_{HT}−VB_{QD}).

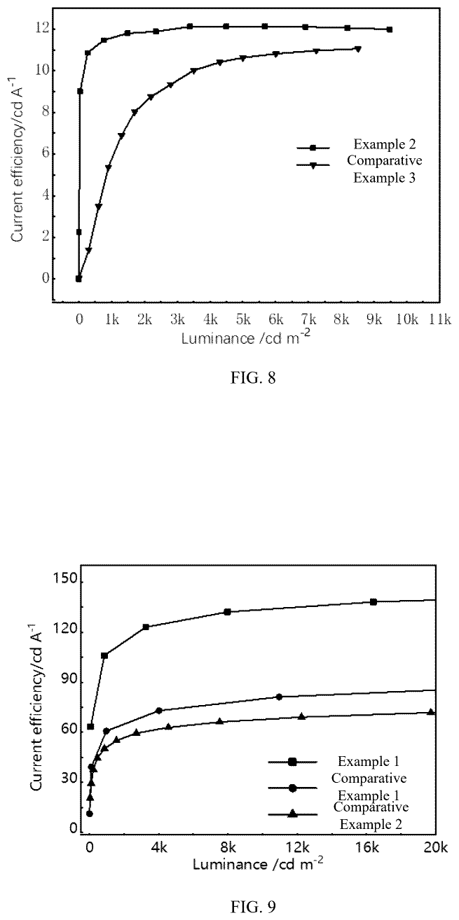

The JVL curves of the light-emitting devices prepared in Example 1, Example 2, Comparative Example 1, Comparative Example 2, and Comparative Example 3 were respectively tested, which were measured by an efficiency test system built by Lab View controlled QE PRO spectrometer, Keithley 2400 and Keithley 6485, where the driving voltage was 0˜4 v and the step size was 0.1 v. The results are shown in FIGS. 7, 8, and 9, respectively. In addition, the maximum current efficiency CE @ max that can be achieved by the above light-emitting device and the efficiency CE @ 500 nit of conventional luminuance (about 500 nit) were tested respectively, and the results are shown in Table 1. Among them, CE @ max represents the maximum current efficiency of the light-emitting device, and CE @ 500 nit is the current efficiency at 500 nits luminuance.

TABLE 1

| | | | Compar- | Compar- | Compar- |
|---|---|---|---|---|---|
| | | | ative | ative | ative |
| | Example 1 | Example 2 | Example 1 | Example 2 | Example 3 |
| CE@max | 140 | 12.1 | 82 | 67 | 10.8 |
| (cd/A) | | | | | |
| CE@500 nit | 105 | 11.1 | 51 | 42 | 3.2 |
| (cd/A) | | | | | |

From the results of FIGS. 7, 8, 9, and Table 1, it can be seen that in the light-emitting device in which the thickness of the light-emitting layer was reduced to 8 nm in Comparative Example 1, leakage occurred when the energization voltage reached around 2.5 V, and both CE @ max and CE @ 500 nit of the light-emitting device were significantly reduced.

The improper matching of the hole transport layer and the quantum dot layer in Comparative Example 2 leads to low CE @ max and CE @ 500 nit.

In Comparative Example 3, the improper matching of the hole transport layer and the quantum dot layer leads to a high CE @ max, but a low CE @ 500nit.

The data in Example 1 and Example 2 are quite different, and the colors of the main devices are different, and the response coefficients of the test instruments are different.

The improper matching of the hole transport layer and the light-emitting layer in Example 2 leads to a high CE @ max, but a low CE @ 500 nit, and the situation is obviously improved after replacing the PVK material meeting the restriction conditions of the present application.

According to Comparative Example 1-3 and Example 1-2, the light-emitting device provided by the present disclosure is described. By limiting the thickness of the light-emitting layer to be greater than or equal to 10 nm in the conventional light-emitting device structure and limiting the energy level matching of the hole transport layer and the light-emitting material of the light-emitting layer to satisfy the condition that the difference value between the conduction band energy level of the light-emitting material of the light-emitting layer and the valence band energy level of the first hole transport material of the hole transport layer is greater than twice the difference value between the valence band energy level of the first hole transport material of the hole transport layer and the valence band energy level of the light-emitting material of the light-emitting layer, the following effects may be achieved: on the premise of maintaining the good efficiency and life of the light-emitting device, the efficiency of the light-emitting device at conventional luminuance may be greatly improved, the performance of the light-emitting device is more in line with commercial application standards. A light-emitting device and a preparation method therefor, and a display apparatus provided by the embodiments of the present disclosure have been described in detail above, and the principle and implementation mode of the present disclosure have been described herein by applying specific examples, and the description of the above embodiments is only for helping to understand the technical solutions and core ideas of the present disclosure; those skilled in the art should understand that the technical solutions described in the above-described embodiments can still be modified, or some technical features can be equivalently replaced. However, these modifications or substitutions do not cause the essence of the corresponding technical solutions to deviate from the scope of the technical solutions of each embodiment of the present application.

1. A light-emitting device, comprising an anode, a hole transport layer made of a first hole transport material, a light-emitting layer made of a light-emitting material, and a cathode; wherein a difference value between a conduction band energy level of the light-emitting material and a valence band energy level of the first hole transport material is a first difference value, a difference value between the valence band energy level of the first hole transport material and a valence band energy level of the light-emitting material is a second difference value; wherein the first difference value is greater than twice the second difference value.

2. The light-emitting device according to claim 1, wherein a thickness of the light-emitting layer is greater than or equal to 10 nm.

3. The light-emitting device according to claim 2, wherein the thickness of the light-emitting layer ranges from 10 nm to 200 nm.

4. The light-emitting device according to claim 1, wherein the light-emitting material is selected from one or more of a single structure quantum dot and a core-shell structure quantum dot, the single structure quantum dot is selected from one or more of a group II-VI compound, a group III-V compound, and a group I-III-VI compound, the group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe and CdZnSTe, the group III-V compound is selected from one or more of InP, InAs, GaP, GaAs, GaSb, AlN, AlP, InAsP, InNP, InNSb, GaAlNP and InAlNP, the group I-III-VI compound is selected from one or more of CuInS₂, CuInSe₂ and AgInSe₂, the core of the core-shell structure quantum dot is selected from any one of the single structure quantum dots, and the shell material of the core-shell structure quantum dot is selected from one or more of CdS, CdTe, CdSeTe, CdZnSe, CdZnS, CdSeS, ZnSe, ZnSeS and ZnS.

5. The light-emitting device according to claim 1, wherein the first hole transport material is selected from one or more of TFB, PVK, poly-TPD, TCATA, CBP, TPD, NPB, PEDOT: PSS, TAPC, doped graphene, undoped graphene, and C60.

6. The light-emitting device according to claim 1, wherein a thickness of the hole transport layer ranges from 10 nm to 100 nm.

7. The light-emitting device according to claim 1, wherein the light-emitting device further comprises a hole injection layer disposed between the hole transport layer and the anode; and, a material of the hole injection layer is selected from one or more of PEDOT: PSS, MCC, CuPc, F4-TCNQ, HATCN, a transition metal oxide and a transition metal chalcogenide compound.

8. The light-emitting device according to claim 1, wherein the light-emitting device further comprises an electron transport layer disposed between the light-emitting layer and the cathode; and/or, a material of the electron transport layer is selected from one or more of nano-zinc oxide, nano-titanium oxide, nano-tin oxide, nano-barium titanate and element-doped nano-oxide electron transport materials thereof, and a doping element is selected from one or more of aluminum element, magnesium element, lithium element, manganese element, yttrium element, lanthanum element, copper element, nickel element, zirconium element, cerium element and gadolinium element.

9. The light-emitting device according to claim 1, wherein a material of the anode is selected from one or more of a metal, a carbon material and a metal oxide, the metal is selected from one or more of Al, Ag, Cu, Mo, Au, Ba, Ca and Mg; the carbon material is selected from one or more of graphite, carbon nanotubes, graphene and carbon fibers; the metal oxide comprises doped or undoped metal oxides, comprising one or more of ITO, FTO, ATO, AZO, GZO, IZO, MZO and AMO, or comprises composite electrodes with metal sandwiched between doped or undoped transparent metal oxides, and the composite electrodes are selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂ and TiO₂/Al/TiO₂.

10. The light-emitting device according to claim 1, wherein a material of the cathode is selected from one or more of a metal, a carbon material and a metal oxide, the metal is selected from one or more of Al, Ag, Cu, Mo, Au, Ba, Ca and Mg; the carbon material is selected from one or more of graphite, carbon nanotubes, graphene and carbon fibers; the metal oxide comprises doped or undoped metal oxides, comprising one or more of ITO, FTO, ATO, AZO, GZO, IZO, MZO and AMO, or comprises composite electrodes with metal sandwiched between doped or undoped transparent metal oxides, and the composite electrodes are selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂.

11. A method for preparing a light-emitting device, comprising:
providing an anode;
stacking a hole transport layer, a light-emitting layer, and a cathode on the anode;
wherein the light-emitting layer is made of a light-emitting material, and the hole transport layer is made of a first hole transport material; a difference value between a conduction band energy level of the light-emitting material and a valence band energy level of the first hole transport material is a first difference value; a difference value between the valence band energy level of the first hole transport material and a valence band energy level of the light-emitting material is a second difference value; wherein the first difference value is greater than twice the second difference value.

12. The method according to claim 11, wherein the light-emitting device further comprises a hole injection layer, and the step of stacking the hole transport layer, the light-emitting layer, and the cathode on the anode comprises:
stacking the hole injection layer, the hole transport layer, the light-emitting layer, and the cathode on the anode.

13. The method according to claim 12, wherein the light-emitting device further comprises an electron transport layer, and the step of stacking the hole injection layer, the hole transport layer, the light-emitting layer, and the cathode on the anode comprises: stacking the hole injection layer, the hole transport layer, the light-emitting layer, the electron transport layer, and the cathode on the anode.

14. The method according to claim 11, wherein a thickness of the light-emitting layer is greater than or equal to 10 nm.

15. The method according to claim 14, wherein the thickness of the light-emitting layer ranges from 10 nm to 200 nm.

16, (canceled)

17. The light-emitting device according to claim 1, wherein the first hole transport material is selected from one or more of doped or undoped NiO, MoOₓ, WOₓ and CuO.

18. A method for preparing a light-emitting device, comprising:
providing a cathode;
stacking a light-emitting layer, a hole transport layer, and an anode on the cathode;
wherein the light-emitting layer is made of a light-emitting material, and the hole transport layer is made of a first hole transport material; a difference value between a conduction band energy level of the light-emitting material and a valence band energy level of the first hole transport material is a first difference value; a difference value between the valence band energy level of the first hole transport material and a valence band energy level of the light-emitting material is a second difference value; wherein the first difference value is greater than twice the second difference value.

19. (New Added) The method according to claim 18, wherein the light-emitting device further comprises a hole injection layer, and the step of stacking the light-emitting layer, the hole transport layer, and the anode on the cathode comprises stacking the light-emitting layer, the hole transport layer, the hole injection layer, and the anode on the cathode.

20. (New Added) The method according to claim 19, wherein the light-emitting device further comprises an electron transport layer, and the step of stacking the light-emitting layer, the hole transport layer, the hole injection layer, and the anode on the cathode comprises stacking the electron transport layer, the light-emitting layer, the hole transport layer, the hole injection layer, and the anode on the cathode.
